(19) United States
(12) Patent Application Publication
(10) Pub. No.: US 2021/0280763 A1
(43) Pub. Date: Sep. 9, 2021

(54) SUPERCONDUCTOR HETEROSTRUCTURES FOR SEMICONDUCTOR-SUPERCONDUCTOR HYBRID STRUCTURES

(71) Applicant: Microsoft Technology Licensing, LLC, Redmond, WA (US)

(72) Inventors: Geoffrey C. GARDNER, West Lafayette, IN (US); Raymond L. KALLAHER, West Lafayette, IN (US); Sergei V. GRONIN, West Lafayette, IN (US); Michael James MANFRA, West Lafayette, IN (US)

(21) Appl. No.: 16/725,710

(22) Filed: Dec. 23, 2019

(51) Int. Cl. H01L 39/22; H01L 39/02; H01L 39/08; H01L 39/24

(52) U.S. Cl. CPC H01L 39/223; H01L 39/025; H01L 39/005; H01L 39/2493; H01L 39/08

(57) ABSTRACT

A semiconductor-superconductor hybrid structure includes a semiconductor layer and a superconductor heterostructure on the semiconductor layer. The superconductor heterostructure includes a first superconductor layer on the semiconductor layer and a second superconductor layer on the first superconductor layer. The first superconductor layer comprises a first superconducting material and the second superconductor layer comprises a second superconducting material that is different from the first superconducting material. By providing the superconductor heterostructure as multiple layers of different superconducting materials, the superconducting and physical properties of the superconductor heterostructure can be improved compared to conventional superconducting homostructures, thereby increasing the performance of the semiconductor-superconductor hybrid structure.

### FIELD OF THE DISCLOSURE

The present disclosure relates to superconductor heterostructures, and in particular to superconductor heterostructures for semiconductor-superconductor hybrid structures such as topological selective-area-growth (SAG) nanowires and superconducting qubits.

### BACKGROUND

Many quantum computing devices such as topological selective-area-growth (SAG) nanowires and superconducting qubits rely on coupling between a semiconductor and a superconductor in a semiconductor-superconductor hybrid structure to provide material characteristics that are suitable for quantum operations. In conventional quantum devices, a superconductor homostructure is provided on a semiconductor to provide a semiconductor-superconductor hybrid structure. The superconductor homostructure is a single superconducting material such as aluminum. Superconducting materials exhibit superconducting properties such as critical temperature, critical field, superconducting gap, 2e periodicity, etc. Further, superconducting materials exhibit physical/structural properties such as melting temperature, etch characteristics, lattice constant, oxidation reactions, etc. The properties of the superconducting material chosen for the superconductor homostructure, along with the properties of the semiconductor on which the superconductor homostructure is provided, determine one or more properties of a semiconductor-superconductor interface between the two such as induced superconducting gap, lattice relationship, etc.

While certain combinations of superconducting materials and semiconductor materials have shown promise for use in quantum computing devices, superconductor homostructures generally fail to provide the properties necessary to create robust and reliable quantum computing devices such as topological SAG nanowires and superconducting qubits. Accordingly, there is a need for improved semiconductor-superconductor hybrid structures for providing quantum computing devices.

### SUMMARY

In one embodiment, a semiconductor-superconductor hybrid structure includes a semiconductor layer and a superconductor heterostructure on the semiconductor layer. The superconductor heterostructure includes a first superconductor layer on the semiconductor layer and a second superconductor layer on the first superconductor layer. The first superconductor layer comprises a first superconducting material, which is chosen to have structural and electrical compatibility with the semiconductor and the second superconductor layer comprises a second superconducting material that is different from the first superconducting material. By providing the superconductor heterostructure as multiple layers of different superconducting materials, the superconducting and physical properties of the superconductor heterostructure can be improved compared to conventional superconducting homostructures, thereby increasing the performance of the semiconductor-superconductor hybrid structure.

In one embodiment, a method for manufacturing a semiconductor-superconductor hybrid structure includes providing a semiconductor layer and providing a superconductor heterostructure on the semiconductor layer. The superconductor heterostructure includes a first superconductor layer on the semiconductor layer and a second superconductor layer on the first superconductor layer. The first superconductor layer comprises a first superconducting material, which is chosen to have structural and electrical compatibility with the semiconductor and the second superconductor layer comprises a second superconducting material that is different from the first superconducting material. By providing the superconductor heterostructure as multiple layers of different superconducting materials, the superconducting and physical properties of the superconductor heterostructure can be improved compared to conventional superconducting homostructures, thereby increasing the performance of the semiconductor-superconductor hybrid structure.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a semiconductor-superconductor hybrid structure including a superconductor heterostructure according to one embodiment of the present disclosure.

FIG. 2 illustrates a semiconductor-superconductor hybrid structure including a superconductor heterostructure according to one embodiment of the present disclosure.

FIG. 3 illustrates a semiconductor-superconductor hybrid structure including a superconductor heterostructure according to one embodiment of the present disclosure.

FIG. 4 is a flow chart illustrating a method for manufacturing a semiconductor-superconductor hybrid heterostructure according to one embodiment of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

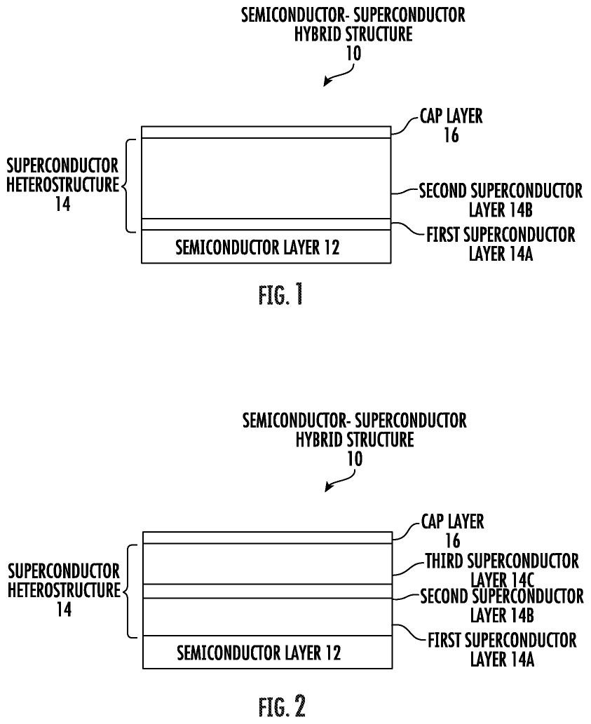

FIG. 1 shows a semiconductor-superconductor hybrid structure 10 according to one embodiment of the present disclosure. The semiconductor-superconductor hybrid structure 10 includes a semiconductor layer 12 and a superconductor heterostructure 14 on the semiconductor layer 12. In some embodiments, an optional cap layer 16 is provided on the superconductor heterostructure 14 to protect the superconductor heterostructure 14 from oxidation. Notably, the superconductor heterostructure 14 includes a first superconductor layer 14A, which is on the semiconductor layer 12, and a second superconductor layer 14B on the first superconductor layer 14A. The first superconductor layer 14A is a first superconducting material, while the second superconductor layer 14B is a second superconducting material that is different from the first superconducting material.

The first superconducting material and the second superconducting material can be chosen to improve certain properties of the superconductor heterostructure 14 without diminishing other properties thereof. As discussed above, in conventional semiconductor-superconductor hybrid structures the superconductor is provided as a homostructure including only one superconducting material. Accordingly, conventional optimization of superconductor properties for a semiconductor-superconductor hybrid structure is limited to the selection of the superconducting material. The properties of the superconductor in conventional semiconductor-superconductor hybrid structures are thus limited by the innate properties of the chosen superconducting material. By using two or more superconducting materials in the superconductor heterostructure 14, it is possible to change the innate limits of the superconductor stack, optimizing for several properties at the same time. Adding superconducting materials to one another in a heterostructure results in changes to the superconducting properties of the heterostructure compared with the individual materials. For example, it has been shown that the superconducting gap can be enhanced by combining superconducting materials. Further, adding superconducting materials to one another results in changes to the physical properties of the heterostructure compared with the individual materials. For example, the melting temperature is nearly linearly related to the concentration of one superconducting material in another. With this in mind, properties such as superconducting gap, critical field, stability during processing, or any other desired properties, may be tuned by combining layers of superconducting materials in the superconductor heterostructure 14.

In various embodiments, the first superconductor layer 14A and the second superconductor layer 14B may comprise different ones of aluminum, lead, niobium, indium, tin, tantalum, and vanadium. The semiconductor layer 12 may comprise indium arsenide, indium antimonide, indium arsenide antimonide, or any other desired semiconductor. The cap layer 16 may comprise aluminum oxide, niobium, or any other suitable metal that is resistant to oxidation. Principles of the present disclosure contemplate semiconductor-superconductor hybrid structures including every combination of the above materials for the first superconductor layer 14A, the second superconductor layer 14B, the semiconductor layer 12, and the cap layer 16. As discussed above, the cap layer 16 may be omitted in some embodiments such as those wherein a superconducting material that is resistant to oxidation (e.g., niobium) is used as the top layer of the superconductor heterostructure 14.

In one embodiment, the first superconductor layer 14A has a thickness between 0.5 nm and 7 nm. The second superconductor layer 14B has a thickness between 3 nm and 30 nm. The semiconductor layer 12 has a thickness between 10 μm and 500 μm. The cap layer 16 has a thickness between 0.5 nm and 10 nm. The semiconductor-superconductor hybrid structure 10 may form a nanowire such that a diameter of the semiconductor-superconductor hybrid structure 10 is on the order of a nanometer (10⁻⁹ meters) and/or has a length to width ratio that is greater than 1000.

As one example, the first superconductor layer 14A may be aluminum and the second superconductor layer 14B may be lead. By combining aluminum and lead in the superconductor heterostructure 14, a topological gap may be increased while maintaining the semiconductor-superconductor interface conduction band offset. The cap layer 16 may maintain the ability to process the semiconductor-superconductor hybrid structure 10 at intermediate temperatures necessary to create quantum devices.

Notably, the first superconductor layer 14A and the second superconductor layer 14B are discrete layers, and are not provided as an alloy. As discussed below, the second superconductor layer 14B is deposited on top of the first superconductor layer 14A as an iterative deposition step.

FIG. 2 shows the semiconductor-superconductor hybrid structure 10 according to an additional embodiment of the present disclosure. The semiconductor-superconductor hybrid structure 10 shown in FIG. 2 is substantially the same as that shown in FIG. 1, except that the superconductor heterostructure 14 includes a third superconductor layer 14C on the second superconductor layer 14B such that the third superconductor layer 14C is between the second superconductor layer 14B and the cap layer 16. The description above of the semiconductor layer 12, the first superconductor layer 14A, the second superconductor layer 14B, and the cap layer 16 applies equally to the embodiment shown in FIG. 2.

The third superconductor layer 14C may be the same superconducting material as the first superconductor layer 14A in some embodiments. For example, the first superconductor layer 14A and the third superconductor layer 14C may be aluminum, while the second superconductor layer 14B may be lead. In other embodiments, the third superconductor layer 14C may be a third superconducting material that is different from both the first superconducting material and the second superconducting material. Similar to the first superconducting material and the second superconducting material, the third superconducting material may be one of aluminum, lead, niobium, indium, tin, tantalum, and vanadium. In the embodiment shown in FIG. 2, a thickness of the first superconductor layer 14A may be between 0.5 nm and 7 nm. A thickness of the second superconductor layer 14B may be between 0.5 nm and 10 nm. A thickness of the third superconductor layer 14C may be between 0.5 nm and 20 nm. More generally, a thickness of at least one of the first superconductor layer 14A, the second superconductor layer 14B, and the third superconductor layer 14C may be less than 3 monolayers in various embodiments.

FIG. 3 shows the semiconductor-superconductor hybrid structure 10 according to an additional embodiment of the present disclosure. The semiconductor-superconductor hybrid structure 10 shown in FIG. 3 is substantially similar to that shown in FIG. 2, except that the superconductor heterostructure 14 includes a fourth superconductor layer 14D on the third superconductor layer 14C such that the fourth superconductor layer 14D is between the third superconductor layer 14C and the cap layer 16. The description above of the semiconductor layer 12, the first superconductor layer 14A, the second superconductor layer 14B, the third superconductor layer 14C, and the cap layer 16 applies equally to the embodiment shown in FIG. 3.

The fourth superconductor layer 14D may be the same superconducting material as the second superconductor layer 14B in some embodiments. In these embodiments, the third superconductor layer 14C may be the same superconducting material as the first superconductor layer 14A. For example, the first superconductor layer 14A and the third superconductor layer 14C may be lead, while the second superconductor layer 14B and the fourth superconductor layer 14D may be niobium. In other embodiments, the fourth superconductor layer 14D may be a fourth superconducting material that is different from the first superconducting material, the second superconducting material, and the third superconducting material, or the same as the first superconducting material. Similar to the first superconducting material, the second superconducting material, the third superconducting material, and the fourth superconducting material may be one of aluminum, lead, niobium, indium, tin, tantalum, and vanadium. In the embodiment shown in FIG. 3, a thickness of the first superconductor layer 14A may be between 0.5 nm and 7 nm. A thickness of the second superconductor layer 14B may be between 0.5 nm and 10 nm. A thickness of the third superconductor layer 14C may be between 0.5 nm and 10 nm. A thickness of the fourth superconductor layer 14D may be between 0.5 nm and 10 nm. More generally, a thickness of at least one of the first superconductor layer 14A, the second superconductor layer 14B, the third superconductor layer 14C, and the fourth superconductor layer 14D may be less than 3 monolayers in various embodiments.

While not shown, the present disclosure contemplates any number of superconductor layers in the superconductor heterostructure 14. For example, the superconductor heterostructure 14 may include 5, 6, 7, 8, 9, 10, or more layers.

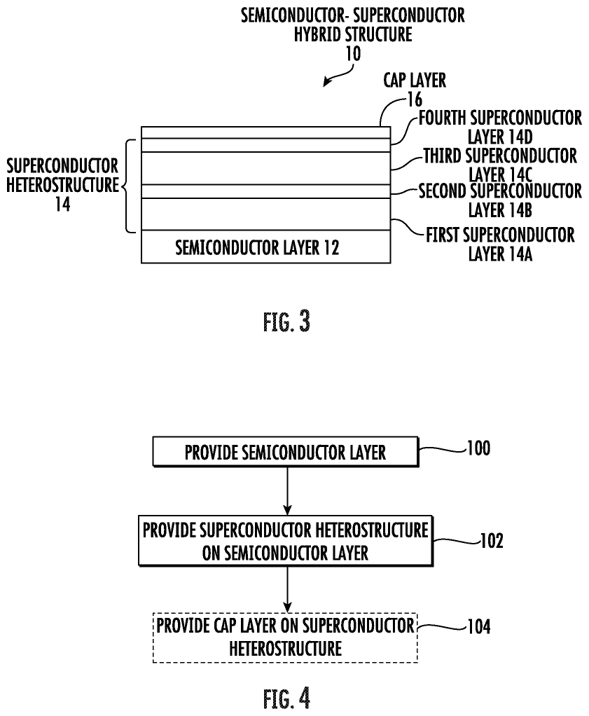

FIG. 4 is a flow diagram illustrating a method for manufacturing the semiconductor-superconductor hybrid structure 10 according to one embodiment of the present disclosure. The method begins by providing the semiconductor layer 12 (block 100). The semiconductor layer 12 may be provided by any suitable process including a SAG process. The superconductor heterostructure 14 is provided on the semiconductor layer 12 (block 102). As discussed above, the superconductor heterostructure 14 includes a number of superconductor layers, each of which may be provided via an iterative deposition step. The superconductor heterostructure 14 may be provided via a molecular beam epitaxy process. Optionally, the cap layer 16 may be provided on the superconductor heterostructure 14 (block 104). The cap layer 16 may be provided by any suitable process.

Those skilled in the art will recognize improvements and modifications to the preferred embodiments of the present disclosure. All such improvements and modifications are considered within the scope of the concepts disclosed herein and the claims that follow.

What is claimed is:

1. A semiconductor-superconductor hybrid structure comprising:
a semiconductor layer; and
a superconductor heterostructure on the semiconductor layer, the superconductor heterostructure comprising a first superconductor layer on the semiconductor layer and a second superconductor layer on the first superconductor layer, wherein the first superconductor layer comprises a first superconducting material and the second superconductor layer comprises a second superconducting material that is different from the first superconducting material.

2. The semiconductor-superconductor hybrid structure of claim 1 wherein the first superconducting material and the second superconducting material comprise one of aluminum, lead, niobium, indium, tin, tantalum, and vanadium.

3. The semiconductor-superconductor hybrid structure of claim 2 wherein the semiconductor layer comprises one of indium arsenide, indium antimonide, and indium arsenide antimonide.

4. The semiconductor-superconductor hybrid structure of claim 1 wherein the superconductor heterostructure further comprises a third superconductor layer on the second superconductor layer.

5. The semiconductor-superconductor hybrid structure of claim 4 wherein the third superconductor layer comprises the first superconducting material.

6. The semiconductor-superconductor hybrid structure of claim 4 wherein the superconductor heterostructure further comprises a fourth superconductor layer on the third superconductor layer.

7. The semiconductor-superconductor hybrid structure of claim 6 wherein the third superconductor layer comprises the first superconducting material and the fourth superconductor layer comprises the second superconducting material.

8. The semiconductor-superconductor hybrid structure of claim 1 wherein the semiconductor-superconductor hybrid structure forms a nanowire.

9. The semiconductor-superconductor hybrid structure of claim 1 wherein a thickness of at least one of the first superconductor layer and the second superconductor layer is less than 3 monolayers.

10. The semiconductor-superconductor hybrid structure of claim 1 further comprising a cap layer on the superconductor heterostructure, wherein the cap layer is configured to protect the superconductor heterostructure from oxidation.

11. A method for manufacturing a semiconductor-superconductor hybrid structure comprising:
providing a semiconductor layer; and
providing a superconductor heterostructure on the semiconductor layer by providing a first superconductor layer on the semiconductor layer and providing a second superconductor layer on the first superconductor layer, wherein the first superconductor layer comprises a first superconducting material and the second superconductor layer comprises a second superconducting material that is different from the first superconducting material.

12. The method of claim 11 wherein the first superconducting material and the second superconducting material comprise one of aluminum, lead, niobium, indium, tin, tantalum, and vanadium.

13. The method of claim 12 wherein the semiconductor layer comprises one of indium arsenide, indium antimonide, and indium arsenide antimonide.

14. The method of claim 11 wherein providing the superconductor heterostructure further comprises providing a third superconductor layer on the second superconductor layer.

15. The method of claim 14 wherein the third superconductor layer comprises the first superconducting material.

16. The method of claim 14 wherein providing the superconductor heterostructure further comprises providing a fourth superconductor layer on the third superconductor layer.

17. The method of claim 16 wherein the third superconductor layer comprises the first superconducting material and the fourth superconductor layer comprises the second superconducting material.

18. The method of claim 11 wherein the first superconductor layer and the second superconductor layer are provided via a molecular beam epitaxy process.

19. The method of claim 18 wherein the semiconductor layer is provided via a selective-area-growth process.

20. The method of claim 11 further comprising providing a cap layer on the superconductor heterostructure, the cap layer configured to protect the superconductor heterostructure from oxidation.
